(19) United States
(12) Patent Application Publication
(10) Pub. No.: US 2004/0108588 A1
(43) Pub. Date: Jun. 10, 2004

(54) Package for microchips

(75) Inventor: Kenneth B. Gilleo, Cranston, RI (US)

Correspondence Address: SENNIGER POWERS LEAVITT AND ROEDEL, ONE METROPOLITAN SQUARE, 16TH FLOOR, ST LOUIS, MO, 63102, US

(73) Assignee: Cookson Electronics, Inc.

(21) Appl. No.: 10/669,901

(22) Filed: Sep. 24, 2003

Related U.S. Application Data
(60) Provisional application No. 60/413,109, filed on Sep. 24, 2002.

(51) Int. Cl. H01L 23/12

(52) U.S. Cl. 257/704

(57) ABSTRACT

A package for protecting an integrated circuit device having an active side. The package includes a substrate for mounting the integrated circuit device and a plastic cap mounted on the substrate to form an enclosed space for the active side of the integrated circuit device. A thermal bond is formed between the substrate and the plastic cap to effectively seal the enclosed space so as to prevent the ingress of moisture or particulate.

### CROSS-REFERENCE TO RELATED APPLICATIONS

This application is a non-provisional of U.S. Provisional Patent Application Serial No. 60/413,109, filed Sep. 24, 2002. The entire text of which is hereby incorporated herein by reference.

### BACKGROUND OF THE INVENTION

The present invention relates generally to packages for microchips, and more particularly to near-hermetic packages for integrated circuit devices and a process for creating such packages.

MEMS, or Micro-Electro-Mechanical Systems, are semiconductor devices that often have moving parts, or microstructures that can cause materials to move (as with thermal ink jet printer chips). A general requirement for packaging MEMS is that no encapsulant or enclosure can make contact with the active surface, or face, of the chip (i.e., die). Even MEMS chips without moving parts, such as radio frequency components including inductor coils, are better served by packages with a free space since encapsulants can “detune” a high-frequency device. If radio frequency components are used, air or vacuum, having a dielectric constant of approximately 1, is the preferred dielectric.

Unfortunately, the conventional low cost packaging method, transfer molding, applies plastic encapsulant over the chip thus rendering most MEMS devices useless. The same is true of liquid encapsulants applied by needle dispensing. Flip chips (i.e., chips attached by Direct Chip Attachment method) cannot be used since underfill that is applied to the area between the chip and the substrate, would cover the active surface. No low cost packaging method for MEMS devices now exists.

The most common package for a MEMS device or other microchip is a metal or ceramic hermetic enclosure that can be conceptually regarded as a tiny box with a lid applied after the chip is inserted and connected. Insulated electrical leads must pass through to the outside of the box thus adding cost and limiting the number of connections. These existing hermetic enclosures are made of metal or ceramic and cost approximately 10 to 100 times more than transfer molded plastic packages. The hermetic lid must be welded, soldered or brazed and this can heat the devices within the enclosure that may be heat-sensitive. Therefore, there is a need for a simple, economical microchip package that is more economical than existing ceramic packages, requires only localized heating to seal the package and provides a higher level of hermeticity than existing plastic packages.

### SUMMARY OF THE INVENTION

Among the several objects of this invention may be noted the provision of a microchip package which is made from low-cost materials, which in a preferred embodiment is plastic; the provision of such a package which provides free space to accommodate integrated circuit devices having moving parts; the provision of such a package which provides a near hermetic seal; the provision of such a package which provides a method of assembly requiring only localized heating to seal the package; the provision of such a package which can be made using an easily automated production process; and the provision of such a package that can be applied to a chip platform substrate or an individual integrated circuit device.

In general, a package of the present invention for protecting an integrated circuit device having an active side comprises a substrate for mounting the integrated circuit device. A plastic cap is mounted on the substrate to form an enclosed space for the active side of the integrated circuit device. A thermal bond is formed between the substrate and the plastic cap to effectively seal the enclosed space so as to prevent the ingress of moisture or particulates.

In another aspect of the invention, the package comprises a plastic cap mounted on the integrated circuit device to form an enclosed space for the active side of the integrated circuit device. A thermal bond is formed between the integrated circuit device and the plastic cap to effectively seal the enclosed space so as to prevent the ingress of moisture or particulates.

In another aspect of the invention, the package comprises a substrate for mounting the integrated circuit device and a cap mounted on the substrate to form an enclosed space for the active side of the integrated circuit device. The cap comprises a metal layer in contact with the substrate. A thermal bond is formed between the substrate and the cap to effectively seal the enclosed space so as to prevent the ingress of moisture or particulates.

In another aspect of the invention, the package comprises a cap mounted on the integrated circuit device to form an enclosed space for the active side of the integrated circuit device. The cap comprises a metal layer in contact with the substrate. A thermal bond is formed between the integrated circuit device and the cap to effectively seal the enclosed space so as to prevent the ingress of moisture or particulates.

Another aspect of the invention is directed to a process for forming a package for protecting an integrated circuit device mounted on a substrate. The process comprises the steps of placing a cap in contact with the substrate such that the cap and the substrate form a junction that defines an enclosed space for the integrated circuit device. Thermal energy is applied to the junction to form a bond between the cap and the substrate, the bond providing a near-hermetic seal for the enclosed space.

In another aspect of the invention the process comprises the steps of placing a cap in contact with the integrated circuit device such that the cap and the integrated circuit device form a junction that defines an enclosed space for the integrated circuit device. Thermal energy is applied to the junction to form a bond between the cap and the integrated circuit device, the bond providing a near-hermetic seal for the enclosed space.

Yet another aspect of the invention is directed to a process for forming an integrated circuit device package comprising the steps of fabricating an integrated circuit device wafer having an active side and fabricating a grid of fusible material. The grid of fusible material is placed on the integrated circuit device wafer. A cap wafer is fabricated and aligned for contact with the grid of fusible material. The cap wafer is placed in contact with the said grid of fusible material. Thermal energy is passed through the integrated circuit device wafer to heat the grid of fusible material and form a bond between the cap wafer and the integrated circuit device wafer. The integrated circuit device wafer and interconnect substrate wafer are diced to form one or more individual integrated circuit device packages having a near hermetically sealed enclosed space.

Other objects and features of the present invention will be in part apparent and in part pointed out hereinafter.

### BRIEF DESCRIPTION OF THE DRAWINGS

FIG. 1 is a schematic of a microchip package of the present invention and a method of assembly to a chip carrier platform;

FIG. 2 is a schematic showing the microchip package and a method of assembly to an integrated circuit device;

FIG. 3 is a schematic showing the microchip package and an alternative method of assembly to an integrated circuit device;

FIG. 4 is a schematic showing an alternate embodiment of the microchip package and a method of assembly to an integrated circuit device;

FIG. 5 is a schematic showing the microchip package of FIG. 5 and an alternative method of assembly to an integrated circuit device;

FIG. 6 is a schematic showing a diode bar laser that can be used to form the microchip package of the present invention;

FIG. 6A is a schematic showing perimeters of radiation that result from the diode bar laser of FIG. 6;

FIGS. 7A-7D are sectional views showing variations of a cap that can be used to form the microchip package of the present invention;

FIG. 8 is a schematic showing a second embodiment of the microchip package of the present invention;

FIGS. 9A-9E are schematics showing steps of an exemplary process for forming microchip packages of the present invention;

FIG. 10 is a schematic of a microchip package of a third embodiment of the present invention and a method of assembly to a chip carrier platform;

FIG. 11 is a schematic showing the microchip package of FIG. 10 and an alternative method of assembly;

FIG. 12 is a schematic of the microchip package of FIG. 10 and an alternative method of assembly to an integrated circuit device;

FIG. 13 is a schematic of a microchip package of a fourth embodiment of the present invention and alternative methods of assembly to a chip carrier platform; and

FIG. 14 is a schematic of the microchip package of FIG. 13 and alternative methods of assembly to an integrated circuit device.

Corresponding parts are designated by corresponding reference numbers throughout the drawings.

### DETAILED DESCRIPTION OF PREFERRED EMBODIMENTS

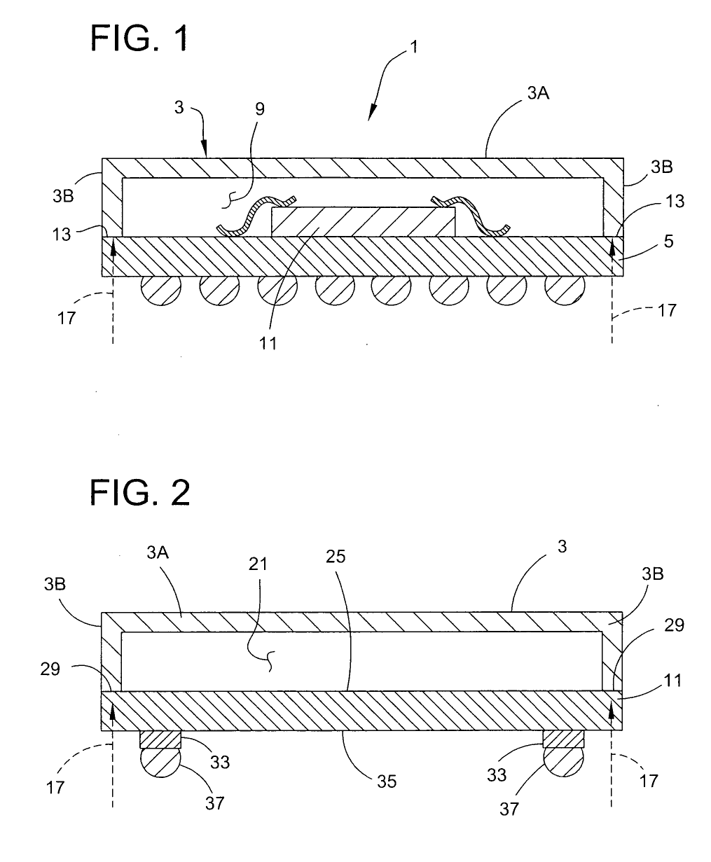

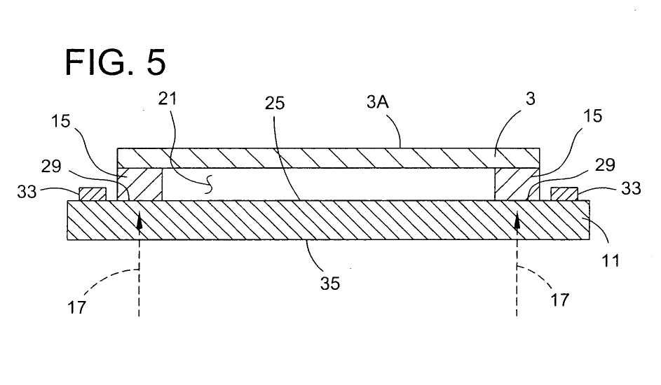

Referring now to the drawings, a microchip package 1 of the present invention comprises two basic parts: a cap 3 and a substrate 5. In the particular embodiment shown in FIG. 1, the substrate is a chip carrier platform also designated 5. The cap 3 is shaped so that an enclosed space 9 is created to accommodate an integrated circuit device (e.g., MEMS device) 11 that requires a protected, open space for the active side of the chip. The enclosed space 9 is hermetically or near-hermetically sealed by thermal bonding at a junction 13 between the cap 3 and the substrate 5. An adhesive film or deposit 15 (FIGS. 4 and 5) is used when the cap 3 and substrate 5 are not made of fusion-bonding materials. In the particular embodiment of FIG. 1, the chip carrier platform 5 is a conventional ball grid array having solder balls 7 for electrical connection to a printed circuit board (not shown), but it will be understood that the platform could comprise other conventional connecting substrates (e.g., a pin-grid array or a land-grid array). Also, the package 1 could enclose and protect more than one integrated circuit (IC) device 11 without departing from the scope of this invention.

The IC device 11 is first bonded and electrically connected to the substrate 5 by conventional chip attachment means such as wire bonding or direct chip attachment (i.e., flip chip). Next, the cap 3 is placed in position on the substrate 5 such that the cap encloses the IC device 11. In one embodiment, the cap 3 has a flat rectangular top wall 3A and rectangular side walls 3B, but it will be understood that the cap may also have other shapes (i.e., circular or dome-shaped). The cap 3 is sealed to the substrate 5 by using photonic radiant thermal energy 17 that causes fusion or at least adhesive-bonding at junction 13 between the cap and the substrate. The fusion or adhesive bonding can be performed in a vacuum or an atmosphere of gas that will become the atmosphere of the sealed package. In one preferred method of assembly, the thermal energy 17 is in the form of an infrared (IR) or near-infrared (NIR) laser passing through the substrate 5 to heat the cap 3. The cap 3 must be able to absorb infrared (IR) or near-infrared (NIR) energy and convert it to heat. However, if the cap 3 is of a material which does not readily form a bond to the substrate 5 by the application of radiant heat, an adhesive film coating, or other layer 15 (FIGS. 4 and 5) can be interposed at junction 13 between the cap and the substrate that will be activated by the radiant energy to form a strong bond.

One preferred cap 3 is made from LCP (Liquid Crystal Polymer), although other high temperature materials can be used including inorganic materials. The preferred cap 3 can be made by injection molding, thermo-forming or any plastic shaping method. Alternatively, the cap 3 can be a planar or non-planar substrate made of ceramic, silicon or even metal. LCP is mostly transparent to IR and NIR radiation necessitating the addition of an absorber to the cap 3. The absorber can be common carbon black filler or a NIR/IR dye, one such dye being based on derivatives of the compound coumarin as sold by Exciton Corporation of Dayton, Ohio. Preferably, the absorber is carbon because plastics, including LCP, are commercially available that contain this filler and it has a wide absorption spectrum. Carbon is also very stable and inert, and used in packaging encapsulants to block light. Carbon has no know toxicological concerns and is environmentally safe. The absorber can be applied to the entire material of the cap 3 or alternatively, can be applied to any portion of the cap that includes a surface adjacent to the junction 13 so that heating at the junction is promoted. Alternatively, absorber may be applied to the substrate 5 to resist the passage of thermal energy and promote heating at junction 13. Since the cap 3 does not make contact with the IC device 11 or wiring structure, it can be electrically conductive. Metal filler can be used in the cap 3 if a radio frequency device requiring shielding is located within the package 1.

The substrate 5 can be an area array type substrate, such as a ball grid array (BGA), a micro-BGA, a Pin Grid Array (PGA), a land grid array or a flip chip. However, any substrate 5 can be used that provides a surface that can be mated to the cap 3 and is somewhat IR/NIR transparent in the perimeter section where the cap is bonded. In manufacture, a series of caps 3 can be temporarily joined together by “runners” (not shown) so that a strip, an array of platforms or even an entire wafer, can be mated with the caps for high productivity. The runners can be cut after the assembly is completed. The substrate 5 can also be in sheet or strip form for higher productivity with singulation occurring after the caps 3 are sealed.

In the embodiment of FIG. 1, a concentrated beam of electromagnetic energy 17 is directed through the substrate 5 to the cap 3 to produce bonding at junction 13. The cap 3 absorbs energy so that sufficient heat is produced to bond the cap to the substrate 5. As mentioned above, a film, adhesive coating or other layer 15 can also be applied at the junction 13 to facilitate the thermal bonding process. The preferred energy source has a wavelength in the IR/NIR range of approximately 700 nanometers to approximately 1 millimeter (more preferably about 806 nanometers) and is produced by a diode laser machine, such as the ELECTROVERT® DLS™ Selective Laser Soldering System manufactured by Cookson Electronics Speedline Division of Camdenton, Mo., having a power ranging from approximately 3-30 watts. However, it will be understood that an energy source having other wavelengths may be used to achieve suitable transmission/absorption relationships. As shown in FIG. 1, the laser beam 17 should be aimed at the junction 13 where heating occurs at the surface of the cap 3. Preferably, the laser beam 17 should pass through the substrate 5 rather than the top of the cap 3 because the substrate will dissipate less thermal energy and allow localized heating at the junction 13. If the laser beam 17 passes through the top wall 3A and side wall 3B of the cap 3, bonding between the cap 3 and substrate 5 will not occur because sufficient thermal heating will not reach the junction 13. Also, passing the laser beam through the top wall 3A of the cap 3 will melt the cap and damage the IC device 11.

As shown in FIGS. 2-5, the cap 3 can also be bonded directly to the individual chip semiconductor material (i.e., wafer, chip, or die) of an IC device 11 to provide an enclosed space 21 directly above the device to protect the active side 25 of the device. In this embodiment, the process used to assemble the cap 3 to the IC device 11 may be a wafer level process that is substantially similar to the process described above for bonding the cap 3 to the substrate 5 (e.g., chip carrier platform). The wafer level process requires that sufficient radiation pass through the semiconductor material 11 to heat the cap 3 so that a bond is formed at junction 29 between the cap and the chip. If the cap 3 and/or the chip 11 are of non-fusion bonding materials, an adhesive film 15 may be used to seal the package. The semiconductor material of the IC device 11 does not need to be fully transparent to IR/NIR radiant thermal energy and some heat generated within the device can be beneficial to the bonding process. However, if too much energy is absorbed by the IC device 11, the components and/or circuitry of the device may be damaged. The preferred energy source for the wafer level process results in highly localized heating where most, or all, of the heating occurs at the localized junction 29 between the cap 3 and the IC device 11.

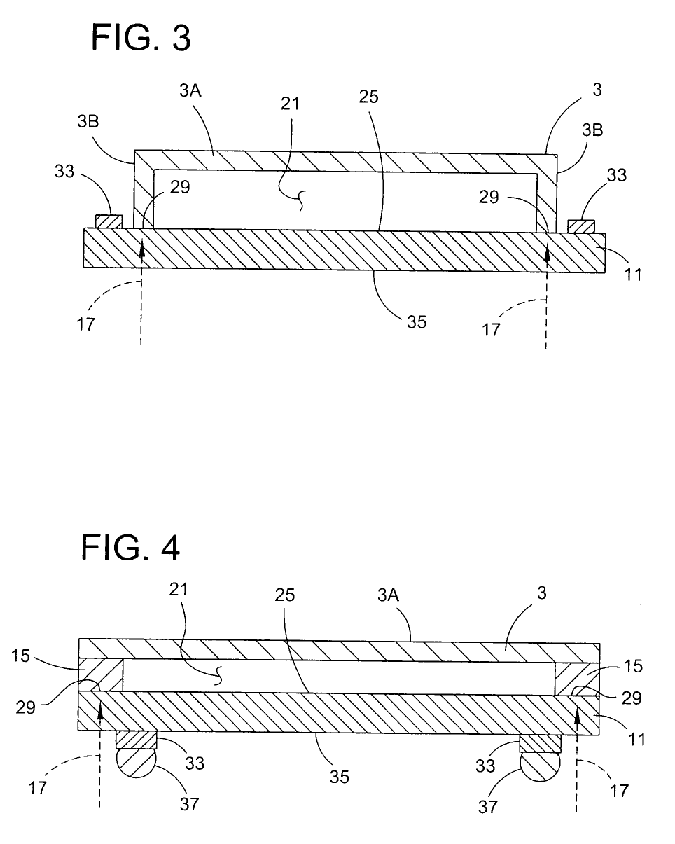

In wafer level processing, the electrical connection pads (i.e., bond pads) 33 of the IC device 11 may be routed from the active side 25 of the device to the back 35 of the chip, as shown in FIGS. 2 and 4. The IC device 11 may have solder balls 37 mounted to the bond pads 33 for flip chip mounting to the substrate 5 or the device may be electrically connected to the substrate by other known chip connection methods. Alternatively as shown in FIGS. 3 and 5, the cap 3 can be sized smaller than the IC device 11 so that the active area 25 above the device is enclosed but the bond pads 33 on the active side of the device are readily accessible. The chip packages illustrated in FIGS. 3 and 5 allow the capped IC device 11 to be wire bonded via bond pads 33 and encapsulated by conventional methods while still protecting the active side 25 of the device. Alternatively, the cap 3 could be fabricated with bond access openings or bonding pads (not shown) in the body of the cap.

The cap 3 can be LCP or virtually any dimensionally stable, but shapable solid that has reasonable strength and presents a good barrier to those liquids and solids that could harm an IC device 11. Ideally, the cap materials have reasonably good gas barrier properties that can be enhanced with coatings, if needed. For example, cap materials can include most engineering plastics or polymers including those materials that are only average barriers since the material can be plated with metal, or a barrier material, such as parylene or a silicone-based materials to improve barrier properties. The polymer families can include acrylics, methacrylics, polycarbonates, polysulfones, urethanes, polyesters, and most engineering thermoplastics. In one preferred embodiment, the cap 3 is injection molded with LCP that contains approximately 0.5% to approximately 30% carbon filler by weight. A small amount of moisture or particulate getter can be bonded or coated to the inside surface of the cap 3 to remove moisture, particles or other contaminants that interfere with IC device operations. Preferred getters, sold by Cookson Electronics of Foxborough, Mass. under the trademark STAYDRY®, consist of desiccants, such as zeolites held in a thermoplastic binder. The getter can be needle dispensed to the inside of the cap 3 and then hardened by heating to evaporate solvent or glued to the inside of the cap. Reference may be made to U.S. Pat. Nos. 5,304,419 and 5,888,925, both of which are incorporated by reference herein for all purposes, for additional information regarding STAYDRY® getters.

The specific size of the cap 3 and the enclosed space 9 and 21 will vary depending on the specific requirements of the enclosed IC device 11. Some IC devices have substantial three dimensional structures that require a larger enclosed space, while others (i.e., accelerometers) are more planar requiring less enclosed space. The cap 3 should be sized to accommodate the additional thickness of any moisture or particulate getter that is applied to the inside of the cap. As discussed above, the cap 3 can be sized to expose chip connection pads 33 on the active side of the IC device 11 or the connection pads may be routed to the back side 25 of the device to facilitate flip chip mounting.

As shown in FIGS. 4-5, the layer 15 may be of an adhesive material when the cap 3 is of a non-fusible material to effectively form the bond attaching the cap to the IC device 11. It will be understood that the adhesive layer 15 can also be added to the embodiment of FIG. 1 where the cap 3 is bonded to the platform 5. Adhesive layer 15 can be a thermoplastic (e.g., LCP), or any material that will absorb radiant energy and create a bond to the cap 3 and substrate 5 or wafer 11. It will be understood that adhesive layer 15 can be a liquid or paste and could also include inorganic materials such as ceramics and glass. Ceramic material commonly referred to as green tape can be used. Green tape is a soft, flexible and formable unfired ceramic material made up of ceramic particles held together in a binder that typically decomposes or vaporizes when the tape is heated to a high temperature (i.e., approximately 400° C. or higher) where the individual particles fuse, or otherwise combine to form a hard, strong and rigid substrate. Alternatively, adhesive layer 15 could be glass frit or other materials that result in a homogenous monolithic substrate after heating. The adhesive 15 can be a free film, a molded grid, or a material applied to the cap 3 by methods including selective dispensing or printing.

In order to form the package 1 of the present invention, the substrate 5 or semiconductor material of the IC device 11 can be any dimensionally stable dielectric that can be formed into a circuit suitable for attaching integrated circuit connections and interconnects on the opposite side for later assembly. The material should have relatively low resistance to the passage of a beam of radiation 17 so that the beam may be converted to heat by the cap 3 or the layer 15 on the cap and/or the platform 11. Fusion bonding between the cap 3 and the substrate 5 or IC device 11 will occur when the photonic energy 17 converted to thermal energy at or near the junction 13, 29 is sufficient to fuse the materials of the package that are capable of melting without decomposition.

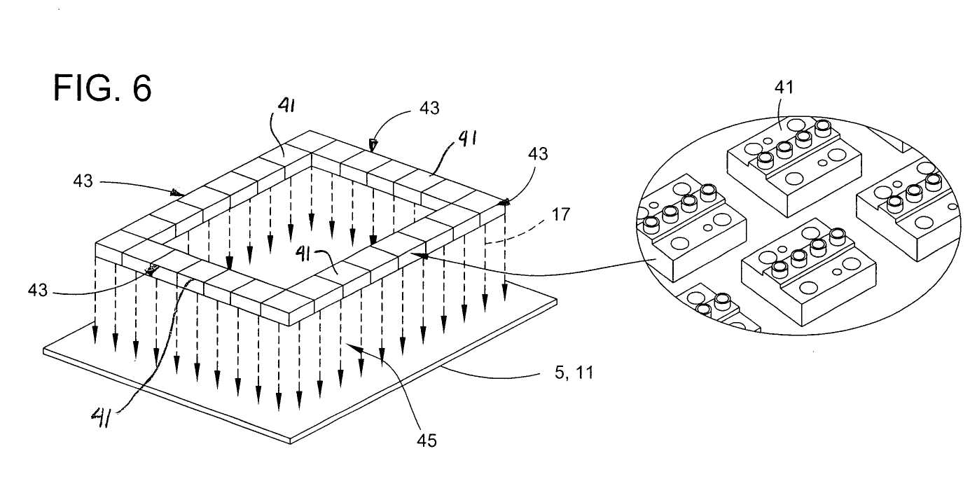

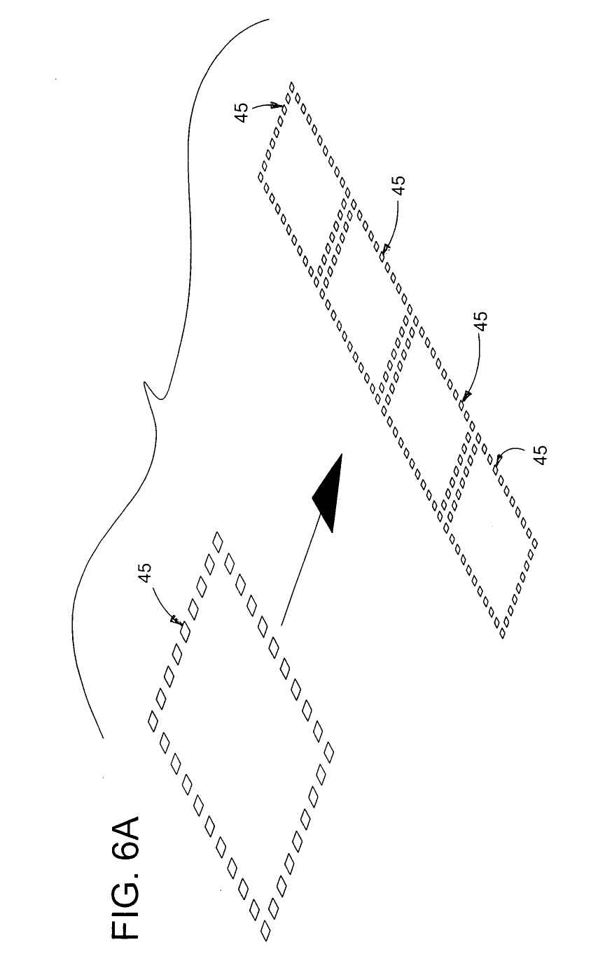

The preferred energy beam is coherent photonic radiation having a wavelength that falls in the NIR/IR part of the light spectrum (i.e., approximately 700 nanometers to 1 millimeter). Specifically, the preferred heating source is a diode bar laser producing an energy beam having a wavelength of approximately 800-825 nanometers and an energy output of at least about 10 watts. As illustrated in FIG. 6, the diode bar laser may consist of individual diodes 41 arranged in a holder 43, to produce a line of radiation 17 approximately equal to the length of one side of the package 1. The holder 43 can be moved into position on the three remaining sides of the package 1 or alternatively, four holders 43 can be arranged to create a perimeter 45 of radiation that corresponds with the respective junction areas, 13 and 29. The radiation 45 passes through the substrate 5 or IC device 11 to heat the junction 13, 29 and form the thermal bond holding the cap 3 to the substrate or IC device. As shown in FIG. 6A, multiple perimeters 45 of radiation can be used to simultaneously bond multiple packages 1 thus reducing processing time and manufacturing costs. Also, the well-known laser process of dithering or scanning can be used to form the package 1 by rapidly moving a single laser beam to heat the corresponding junction areas, 13 and 29.

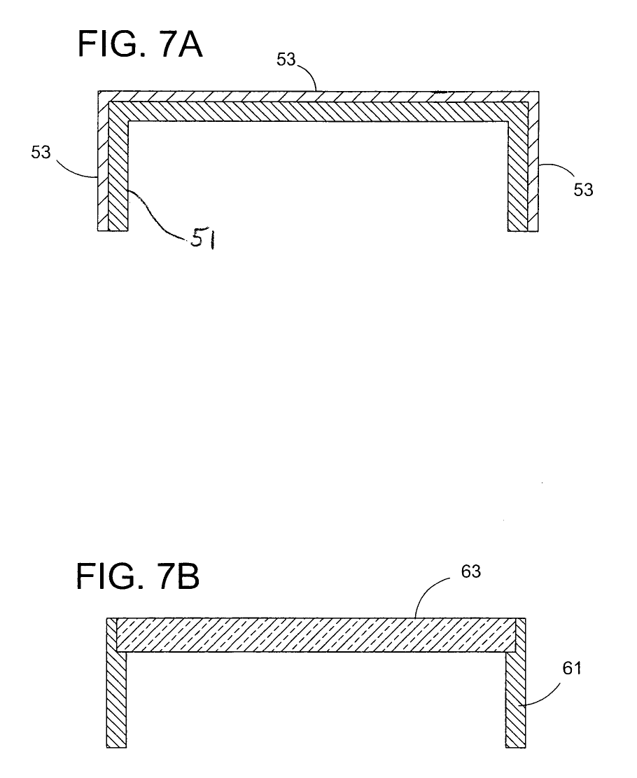

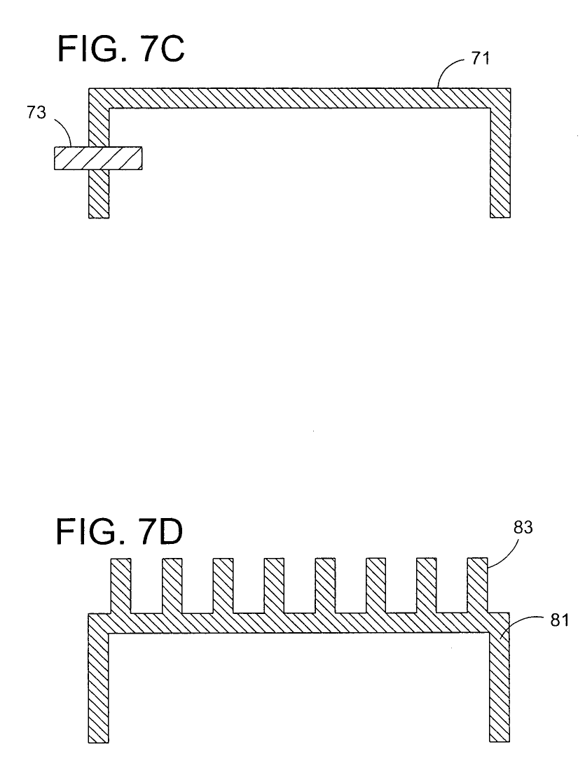

FIGS. 7A thru 7D show some of the possible variations of the cap 3 that can be used in any of the above processes to form the microchip package 1 of the present invention. All variations of the cap 3 may optionally include thermally conductive fillers such as carbon, metal, minerals, or any mixture of these materials. FIG. 7A illustrates a cap 51 that includes a metal coating 53 applied to the outer surface of the cap by conventional means (i.e., plating, vacuum deposition, or spraying). FIG. 7B illustrates a cap 61 having a window 63 made of glass, metal, plastic, or ceramic, for example, that can be post bonded or insert molded into the cap. The window 63 allows the passage of optical signals to the IC device 11 enclosed by the cap 61 so that the enclosed device may be an optoelectronic (OE) or optical-MEMS device capable of receiving light signals. FIG. 7C illustrates a cap 71 having a port 73 that can house fiber optics, lenses, tubing, or filters that selectively permit entry of materials that can be tested by the IC device 11 sealed within package 1. FIG. 7D illustrates a cap 81 having cooling fins 83 that run the length of the cap and can alternatively operate as heat sinks.

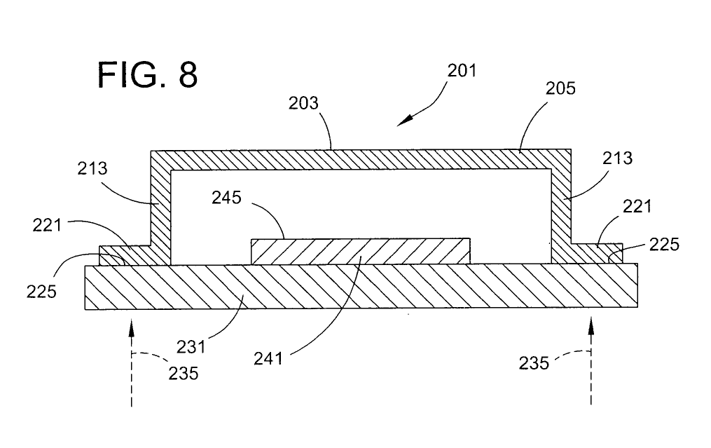

FIG. 8 illustrates an additional embodiment of a microchip package 201, generally similar to the embodiment of FIG. 1. The cap 203 of this embodiment has a top wall 205, a depending side wall 213, and a peripheral flange 221 extending laterally outwardly from the side wall 213 adjacent its lower edge to form a junction 225 with the substrate 231. The flange 221 can be a single long flange running continuously around the entire perimeter of the cap, or one or more shorter flanges extending along one or more portions of the perimeter of the cap. Thermal energy in the form of a laser beam 235 passes through the substrate 231 to heat the junction 225 and produce a thermal bond between the cap 203 and the substrate 231 that effectively seals the microchip package 201. As in the previous embodiments, the cap 203 of this embodiment could be attached directly to an IC device 241 to enclose and protect the active side 245 of the device. It will be understood that the cap 203 of this embodiment may comprise any of the materials disclosed above for the cap 3 of the previous embodiment (e.g, LCP with radiation absorber, ceramic, silicon, metal, etc.). As in the previous embodiments, the package 201 could comprise an adhesive layer at the junction 225 between the cap 203 and the substrate 231 to strengthen the bond that seals the package. Such an adhesive layer may be necessary when the cap 203 is made from a non-fusible material that resists bonding with the material of the substrate 231.

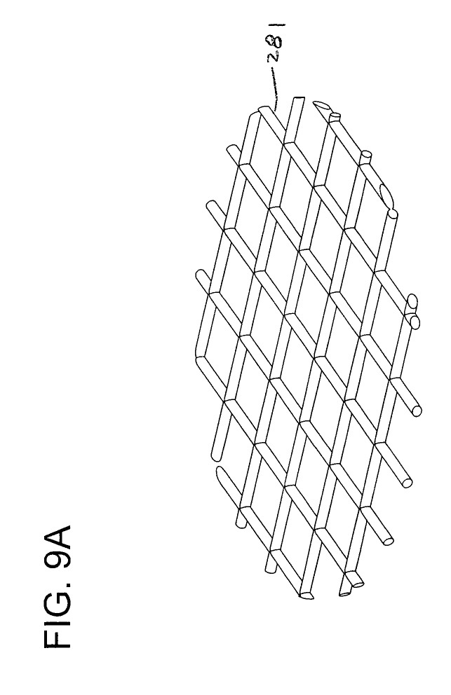

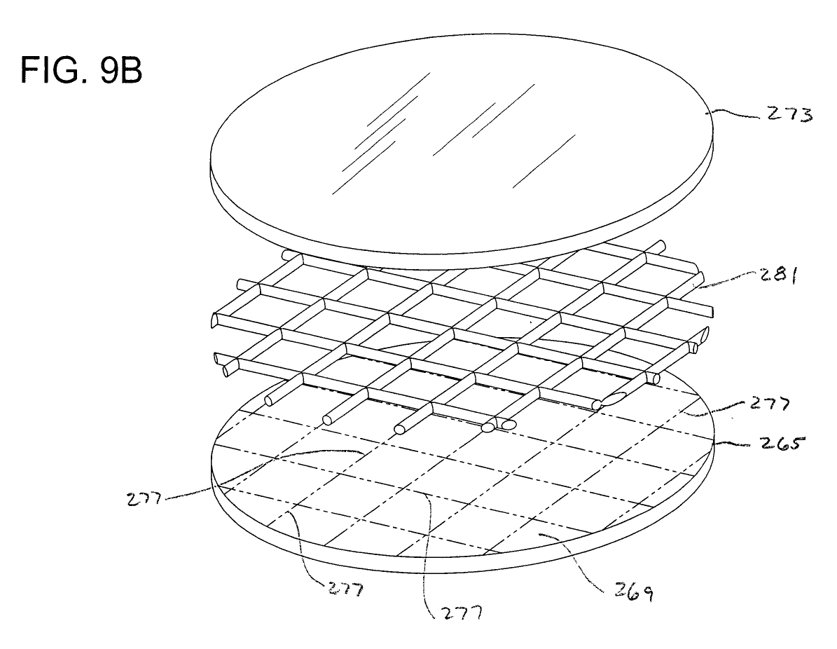

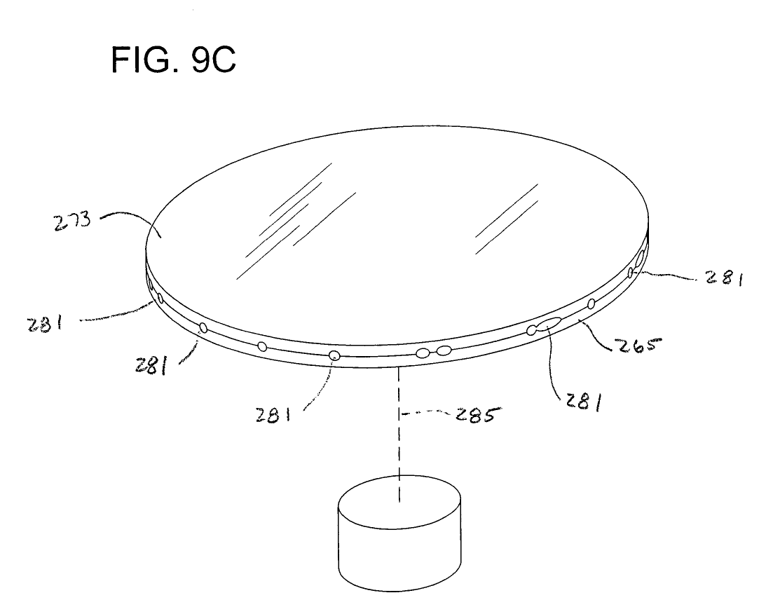

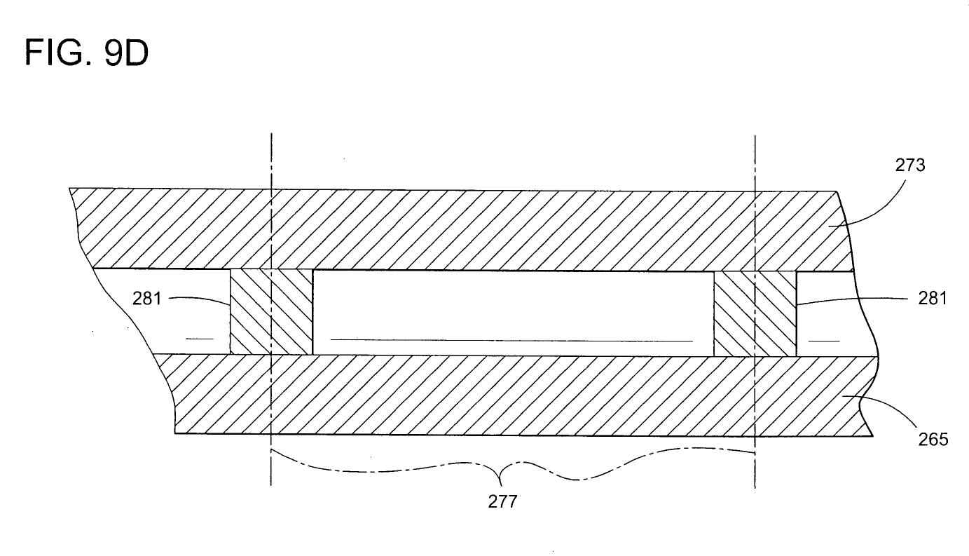

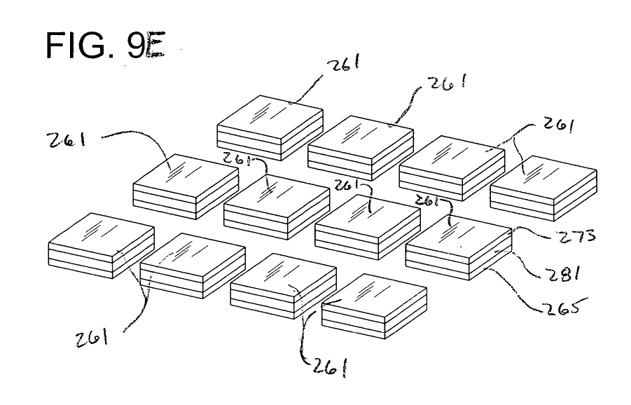

FIGS. 9A-9E illustrate a wafer level fabrication process for making a plurality of individual integrated circuit device packages 261 (see FIG. 9E). The process comprises fabricating an IC device wafer 265 having an active side 269 and fabricating a cap wafer 273 that is sized to mate with the IC device wafer. The IC device wafer 265 may carry a plurality of MEMS devices or other IC devices (not shown) that have been mounted or fabricated on the wafer by traditional methods. As seen in FIG. 9B, the IC device wafer 365 has a number of cut lines 277 in the shape of a grid that represent the peripheral edges of the individual IC devices on the wafer. Reference may be made to U.S. Pat. Nos. 6,475,881; 6,159,826; 5,981,361; and 5,685,885, incorporated by reference herein for all purposes, for details of conventional wafer fabrication processes. As seen in FIGS. 9A and 9B, a grid of fusible material (e.g., LCP or other thermoplastic) 281 is fabricated to correspond with the cut lines 277 of the IC device wafer 265 and is placed in contact with the IC device wafer so that the lines of the grid are in registration with the cut lines. As shown in FIG. 9D, the cap wafer 273 is aligned for contact with the grid of fusible material 281 and is pressed into contact with the grid so that the fusible material forms a junction between the cap wafer and the IC device wafer 265. Thermal energy in the form of a laser 285 is passed through the IC device wafer 265 along the cut lines 277 to heat the grid of fusible material 281 at the junction between the cap wafer 273 and IC device wafer to form a bond between the wafers. The thermal energy 285 may be generated by a diode laser as described above and shown in FIGS. 6 and 6A. After bonding, the joined wafers 265, 273 are diced by conventional dicing methods (e.g., laser cutting or sawing). In one embodiment, the wafers 265, 273 are diced along the cut lines 277 of the IC device wafer through the grid of fusible material 281 that is bonded to the cap wafer and the IC device wafer (FIG. 9D). As shown in FIG. 9E, the diced wafers 265, 273 result in individual integrated circuit device packages 261 having a near hermetically sealed enclosed space above the active side of the IC device. Alternatively, the grid 281 of fusible material can be replaced by an adhesive layer in the form of paste that is applied to the bottom of the cap wafer prior to placing the cap wafer on the IC device wafer.

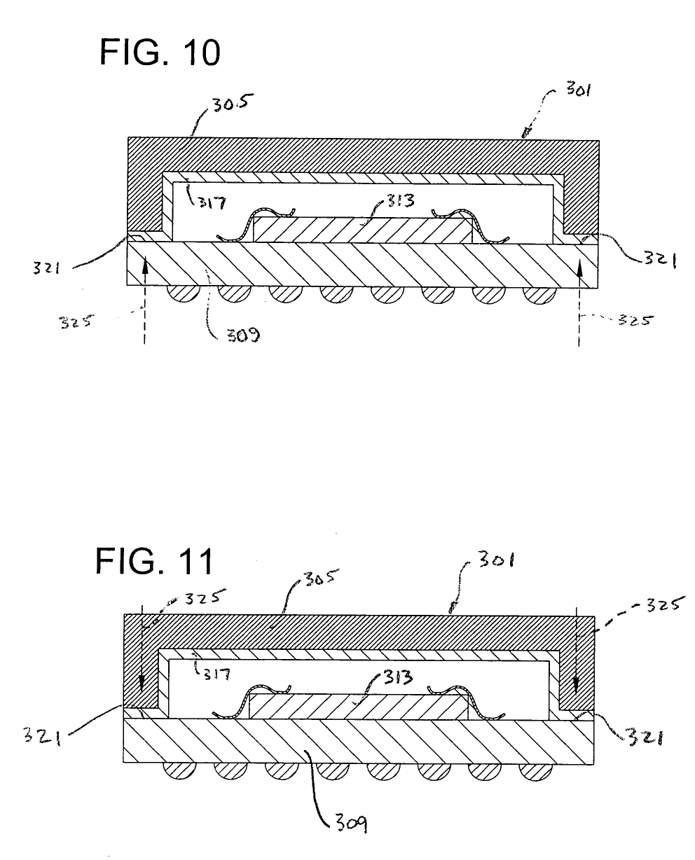

FIGS. 10-12 illustrate another embodiment of an IC device package of this invention, generally indicated 301. This embodiment is substantially similar to the first embodiment in that the package 301 comprises a cap 305. Portions of this layer 317 are bonded to the substrate 309 that carriers an IC device 313. In this embodiment, the package 301 comprises a metal layer 317 on the inner surface of the cap 305 that is positioned at the junction 321 between the substrate 309 and the cap. In this embodiment, the cap 305 may comprise any fusible material (e.g., plastic or glass) or any non-fusible material (e.g., ceramic). Also the cap 305 may comprise material that is transparent or non-transparent to IR/NIR radiation. As shown in FIG. 10, bonding between the cap 305 and the substrate 309 may be achieved by passing thermal energy 325 through the substrate 309 to heat the junction 321 between the cap and the substrate to create a thermal bond between the metal layer 317 and the substrate. A thin layer of solder (not shown) may be interposed between the metal layer 317 of the cap and the substrate 309 to facilitate bonding. Preferably, the metal layer 317 comprises a material that has a melting point above typical solder melting points (e.g., at least 250° C.). The metal layer 317 may be nickel or copper plating and may be deposited on the inner surface of the cap 305 by any conventional process such as electroplating. The metal layer 317 may comprise a thin gold coating (i.e., immersion gold or gold flash) to prevent oxidation and maintain solderability. The metal layer 317 may comprise portions of the inner surface of the cap 305 at the junction 321 or the layer may comprise other portions of the inner surface of the cap not located at the junction without departing from the scope of this invention.

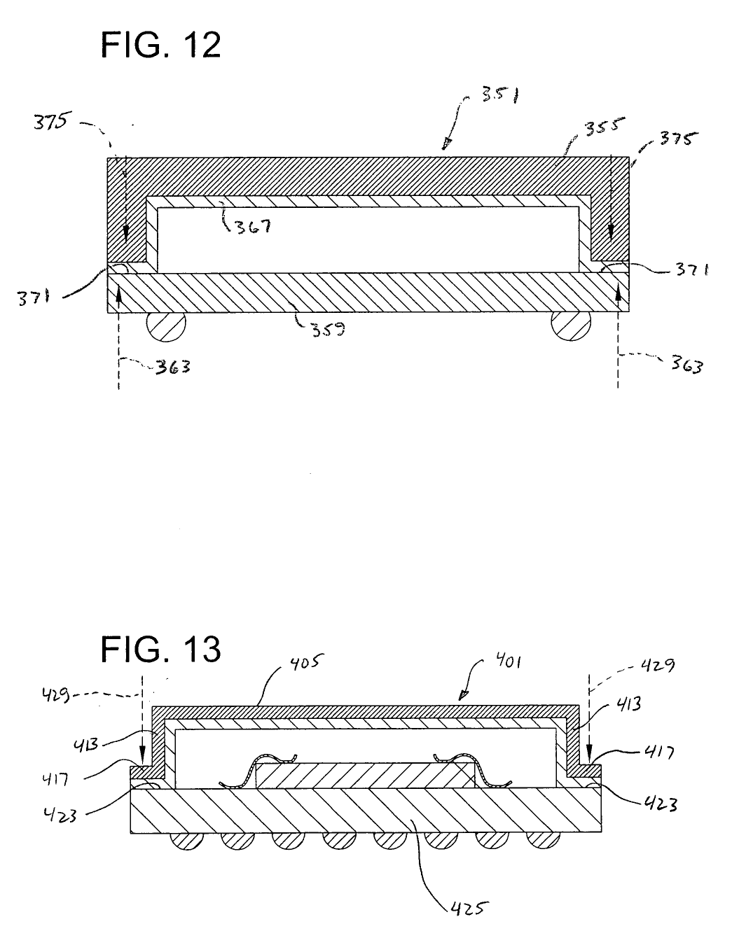

As shown in FIG. 11, the thermal (e.g., laser) energy 325 may be directed through the top of the cap 305 to heat the metal layer 317 at the junction 321 between the cap and the substrate 309. In this embodiment, the cap 305 comprises a material that is transparent to IR/NIR radiation so that the thermal energy 325 passes through the cap and heats the metal layer 317 to cause bonding between the cap and the substrate 309. Typical materials for the cap 305 of this embodiment include LCP and glass. If the cap 305 comprises LCP, a filler should be used that does not absorb IR/NIR energy or the filler should be omitted from the cap material. As with the previous embodiment, the metal layer 317 may be any metal that has a melting point above solder reflow temperatures (e.g., at least about 250° C.) and may include a thin layer of solder between the metal layer and the substrate 309 to facilitate bonding of the cap 305 to the substrate. FIG. 12 shows an alternative embodiment of the IC device package, generally designated 351, that is substantially similar to the package 301 except the cap 355 is sized for bonding directly to the IC device 359. As with the previous embodiment, the package 351 may be formed by passing thermal energy 363 through the IC device 359 to heat the metal layer 367 that lines the inside of the cap 355 to create a thermal bond at the junction 371 between the cap and the IC device. Alternatively, the cap 355 could comprises material that is transparent to the passage of IR/NIR radiation so that thermal energy 375 may be directed through the top of the cap 355 to heat the junction 371 between the cap and the substrate.

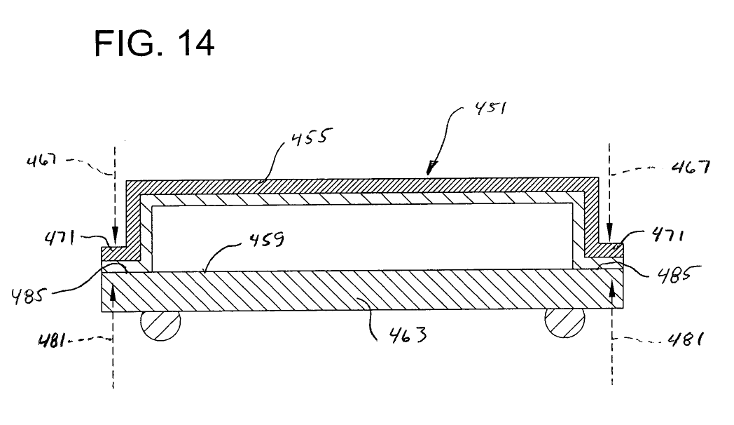

FIG. 13 shows an alternate embodiment of an IC device package of this invention, generally designated 401. This embodiment has a cap 405 that is shaped substantially similar to the embodiment of FIG. 8 in that the cap has a top wall 409, depending side walls 413, and a peripheral flange 417 extending laterally outwardly from the side walls adjacent their lower edges. The package 401 of this embodiment includes a metal layer 421 on the inside surface of the cap 405 that is substantially similar to the metal layer 317 in the embodiment of FIG. 10. The metal layer 421 on the surface of the peripheral flange 417 forms a junction 423 between the cap 405 and the substrate 425. The package 401 of this embodiment may be formed by passing thermal energy 429 through the top of the flange 417 of the cap 405 to heat the metal layer 421 at the junction 423 between the cap and the substrate 425. The localized heating at the junction 423 causes a thermal bond between the cap 405 and substrate 425 that provides a near-hermetic seal of the package 401. As shown in FIG. 14, a similar IC device package, generally designated 421, that is smaller in size than the embodiment of FIG. 13 maybe formed by bonding a cap 455 directly to the active side 429 of an IC device 463. The cap 455 is substantially similar to the cap 405 of FIG. 13 except the cap is sized to enclose the active side 459 of the IC device 463. The cap 455 may be bonded to the IC device 463 by passing thermal energy 467 through the peripheral flange 471 of the cap to form a thermal bond between the cap and the IC device. Alternatively, thermal energy 481 may be passed through the IC device 463 to heat the junction 485 between the IC device and the cap 455.

In view of the above, it will be seen that the several objects of the invention are achieved and other advantageous results attained.

As various changes could be made in the above constructions without departing from the scope of the invention, it is intended that all matter contained in the above description or shown in the accompanying drawings shall be interpreted as illustrative and not in a limiting sense.

When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

What is claimed is:

1. A package for protecting an integrated circuit device having an active side, said package comprising:
a substrate for mounting the integrated circuit device;
a plastic cap mounted on the substrate to form an enclosed space for the active side of the integrated circuit device;
a thermal bond formed between the substrate and the plastic cap to effectively seal the enclosed space so as to prevent the ingress of moisture or particulates.

2. The package as set forth in claim 1 wherein said plastic cap comprises a liquid crystal polymer.

3. The package as set forth in claim 1 wherein said plastic cap comprises an absorber material to resist the passage of radiant energy through the cap.

4. The package as set forth in claim 3 wherein said absorber material comprises carbon black filler.

5. The package as set forth in claim 1 wherein said plastic cap comprises a metal layer on an outer surface of the cap to provide radio frequency shielding of the integrated circuit device.

6. The package as set forth in claim 1 wherein said plastic cap comprises a transparent panel for the passage of optical signals to the integrated circuit device.

7. The package as set forth in claim 1 wherein said plastic cap comprises a port for the selective entry of materials into the package.

8. The package as set forth in claim 1 wherein said plastic cap comprises cooling fins for the dissipation of heat from the package.

9. The package as set forth in claim 1 further comprising an adhesive coating between the plastic cap and the substrate to bond the cap to the substrate.

10. The package as set forth in claim 1 wherein said thermal bond is located at a junction between the plastic cap and the substrate.

11. The package as set forth in claim 10 wherein said plastic cap comprises a metal coating at the junction between the cap and the substrate.

12. The package as set forth in claim 11 wherein said metal coating is nickel plating.

13. A package for protecting an integrated circuit device having an active side, said package comprising:
a plastic cap mounted on the integrated circuit device to form an enclosed space for the active side of the integrated circuit device;
a thermal bond formed between the integrated circuit device and the plastic cap to effectively seal the enclosed space so as to prevent the ingress of moisture or particulates.

14. The package as set forth in claim 13 wherein said plastic cap comprises a liquid crystal polymer.

15. The package as set forth in claim 13 wherein said plastic cap comprises an absorber material to resist the passage of radiant energy through the cap.

16. The package as set forth in claim 15 wherein said absorber material comprises carbon black filler.

17. The package as set forth in claim 13 wherein said plastic cap comprises a metal layer on an outer surface of the cap to provide radio frequency shielding of the integrated circuit device.

18. The package as set forth in claim 13 wherein said plastic cap comprises a transparent panel for the passage of optical signals to the integrated circuit device.

19. The package as set forth in claim 13 wherein said plastic cap comprises a port for the selective entry of materials into the package.

20. The package as set forth in claim 13 wherein said plastic cap comprises cooling fins for the dissipation of heat from the package.

21. The package as set forth in claim 13 further comprising an adhesive coating between the plastic cap and the substrate to mechanically attach the cap to the integrated circuit device.

22. The package as set forth in claim 13 wherein said thermal bond is located at a junction between the plastic cap and the integrated circuit device.

23. The package as set forth in claim 22 wherein said cap comprises a metal coating at the junction between the plastic cap and the integrated circuit device.

24. The package as set forth in claim 23 wherein said metal coating is nickel plating.

25. A package for protecting an integrated circuit device having an active side, said package comprising:
a substrate for mounting the integrated circuit device;
a cap mounted on the substrate to form an enclosed space for the active side of the integrated circuit device, the cap comprising a metal layer in contact with the substrate;
a thermal bond formed between the substrate and the cap to effectively seal the enclosed space so as to prevent the ingress of moisture or particulates.

26. The package as set forth in claim 25 wherein said cap comprises plastic.

27. The package as set forth in claim 25 wherein said cap comprises ceramic.

28. The package as set forth in claim 25 wherein said cap comprises glass.

29. The package as set forth in claim 25 wherein said metal layer comprises nickel.

30. The package as set forth in claim 25 wherein said metal layer comprises copper.

31. A package for protecting an integrated circuit device having an active side, said package comprising:
a cap mounted on the integrated circuit device to form an enclosed space for the active side of the integrated circuit device, the cap comprising a metal layer in contact with the substrate;
a thermal bond formed between the integrated circuit device and the cap to effectively seal the enclosed space so as to prevent the ingress of moisture or particulates.

32. The package as set forth in claim 31 wherein said cap comprises plastic.

33. The package as set forth in claim 31 wherein said cap comprises ceramic.

34. The package as set forth in claim 31 wherein said cap comprises glass.

35. The package as set forth in claim 31 wherein said metal layer comprises nickel.

36. The package as set forth in claim 31 wherein said metal layer comprises copper.

37. A process for forming a package for protecting an integrated circuit device mounted on a substrate comprising the steps of:
placing a cap in contact with the substrate such that said cap and said substrate form a junction and define an enclosed space for the integrated circuit device; and
applying thermal energy to the junction to form a bond between the cap and the substrate, said bond providing a near-hermetic seal for the enclosed space.

38. The process as set forth in claim 37 wherein said steps of applying thermal energy comprises using a laser to pass a beam of energy through the substrate to heat the junction.

39. The process as set forth in claim 38 wherein said beam of energy has a wavelength of approximately 800 nanometers to approximately 825 nanometers.

40. The process as set forth in claim 37 wherein said cap comprises a metal coating in contact with the substrate to form said junction, said step of applying thermal energy comprises using a laser to pass a beam of energy through the cap to heat the junction.

41. A process for forming a package for protecting an integrated circuit device comprising the steps of:
placing a cap in contact with the integrated circuit device such that said cap and said integrated circuit device form a junction and define an enclosed space for the integrated circuit device; and
applying thermal energy to the junction to form a bond between the cap and the integrated circuit device, said bond providing a near-hermetic seal for the enclosed space.

42. The process as set forth in claim 41 wherein said step of passing thermal energy comprises using a laser to pass a beam of energy through the integrated circuit device to heat the junction.

43. The process as set forth in claim 42 wherein said beam of energy has a wavelength of approximately 800 nanometers to approximately 825 nanometers.

44. The process as set forth in claim 41 wherein said cap comprises a metal coating in contact with the integrated circuit device to form said junction, said step of applying thermal energy comprises using a laser to pass a beam of energy through the cap to heat the junction.

45. A process for forming an integrated circuit device package, the process comprising the steps of:
fabricating an integrated circuit device wafer having an active side;
fabricating a grid of fusible material and placing the material on the integrated circuit device wafer;
fabricating a cap wafer and aligning said wafer for contact with the grid of fusible material;
placing said cap wafer in contact with said grid of fusible material;
passing thermal energy through the integrated circuit device wafer to heat the grid of fusible material and form a bond between the cap wafer and the integrated circuit device wafer; and
dicing the integrated circuit device wafer and cap wafer to form one or more individual integrated circuit device packages each having a near hermetically sealed enclosed space.
